(19) United States
(12) Patent Application Publication
(10) Pub. No.: US 2026/0094638 A1
(43) Pub. Date: Apr. 2, 2026

(54) MEMORY DEVICE AND SYSTEM-IN-PACKAGE INCLUDING THE SAME

(71) Applicant: Samsung Electronics Co., Ltd., Suwon-si (KR)

(72) Inventors: Ilho JUNG, Suwon-si (KR); Youngwook KWON, Seoul (KR); Chulwoo KIM, Seoul (KR); Kwanyeob CHAE, Suwon-si (KR)

(73) Assignees: Samsung Electronics Co., Ltd., Suwon-si (KR); KOREA UNIVERSITY RESEARCH AND BUSINESS FOUNDATION, Seoul (KR)

(21) Appl. No.: 19/331,610

(22) Filed: Sep. 17, 2025

(30) Foreign Application Priority Data
Sep. 27, 2024 (KR) 10-2024-0132127
Nov. 14, 2024 (KR) 10-2024-0162521

(51) Int. Cl. G11C 11/4076; H01L 25/065; H01L 25/18; H10B 80/00

(52) U.S. Cl. CPC G11C 11/4076; H10B 80/00; H10W 90/00; H10W 90/297; H10W 90/722; H10W 90/724

(57) ABSTRACT

A memory device includes a physical layer (PHY) interface, and a memory cell array. The PHY interface includes a phase adjusting circuit configured to generate a plurality of phase-shifted clock signals and a phase-shifted training clock signal based on a clock signal and configured to delay the clock signal based on a plurality of comparison signals output from a comparator, the comparator configured to compare training data with each of a first reference voltage and a second reference voltage based on the plurality of phase-shifted clock signals and the phase-shifted training clock signal to output the plurality of comparison signals, the plurality of comparison signals including first comparison signals based on the plurality of phase-shifted clock signals, and second comparison signals based on the plurality of phase-shifted clock signals and the phase-shifted training clock signal, and a decoder configured to perform a duo-binary decoding on the first comparison signals.

### CROSS-REFERENCE TO RELATED APPLICATIONS

This U.S. non-provisional application claims priority under 35 U.S.C. § 119 to Korean Patent Application Nos. 10-2024-0132127, filed on Sep. 27, 2024, and 10-2024-0162521, filed on Nov. 14, 2024, in the Korean Intellectual Property Office, the disclosures of which are incorporated by reference herein in their entirety.

### BACKGROUND

Applications related to, for instance, big data, artificial intelligence, and machine learning, may use increased amount of data. It is advantageous for memory devices used by these applications to operate with a relatively higher speed and to have relatively higher bandwidth for communication.

Higher bandwidth for communication between memory devices and memory controllers may be obtained by increasing the number of communication channels therebetween. As the number of the communication channels increases, a distance between the communication channels may decrease, and it is beneficial to reduce channel interference and crosstalk between the communication channels.

### SUMMARY

Example embodiments relate to a memory device, a system-in-package including the memory device, and a method of operating the memory device. Example embodiments also relate to a technology that may provide a relatively high-speed communication between the memory device and a memory controller with improved reliability.

Example embodiments provide a physical layer interface to perform communication between a memory device and a memory controller with a relatively higher speed and with improved reliability.

According to some example embodiments, a memory device includes a physical layer (PHY) interface and a memory cell array. The PHY interface includes a phase adjusting circuit that is configured to generate a plurality of phase-shifted clock signals and a phase-shifted training clock signal based on a clock signal and configured to delay the clock signal based on a plurality of comparison signals output from a comparator. The comparator is configured to compare training data with each of a first reference voltage and a second reference voltage based on the plurality of phase-shifted clock signals and the phase-shifted training clock signal to output the plurality of comparison signals. The plurality of comparison signals including first comparison signals based on the plurality of phase-shifted clock signals, and second comparison signals based on the plurality of phase-shifted clock signals and the phase-shifted training clock signal. The PHY interface also includes a decoder configured to perform a duo-binary decoding on the first comparison signals.

According to some example embodiments, a memory device includes a buffer die comprising a PHY interface, a core die comprising a memory cell array and on the buffer die, and a through-silicon via penetrating through the core die. The PHY interface includes a clock signal generating circuit configured to generate a plurality of phase-shifted clock signals based on a clock signal, a comparator configured to compare a received data signal sampled based on the phase-shifted clock signals with each of a first reference voltage and a second reference voltage and configured to output first comparison signals, a decoder configured to perform a duo-binary decoding on the first comparison signals, a delay circuit configured to delay the clock signal, and a phase detecting circuit configured to control the delay circuit. The phase detecting circuit is further configured to generate a phase-shifted training clock signal having a phase different from the phase-shifted clock signals during a training operation. The comparator is further configured to output second comparison signals obtained by comparing the received data signal sampled based on the phase-shifted training clock signal with each of the first reference voltage and the second reference voltage during the training operation. The phase detecting circuit is configured to control the delay circuit based on the first comparison signals and the second comparison signals during the training operation.

According to some example embodiments, a system-in-package includes a package substrate, an interposer on the package substrate, and a memory device and a system-on-chip on the interposer. The memory device includes a buffer die comprising a PHY interface, core dies on the buffer die, and a through-silicon via penetrating through the core dies. The PHY interface includes a phase adjusting circuit that is configured to generate a plurality of phase-shifted clock signals and a phase-shifted training clock signal based on a clock signal received from the system-on-chip and configured to delay the clock signal based on a plurality of comparison signals output from a comparator. The comparator is configured to compare training data received from a memory controller with each of a first reference voltage and a second reference voltage based on the phase-shifted clock signals and the phase-shifted training clock signal to output the plurality of comparison signals. The decoder is configured to perform a duo-binary decoding on the comparison signals based on the phase-shifted clock signals.

According to some example embodiments, a method of operating a memory device includes receiving a clock signal and training data, the training data including a duo-binary signal, generating a plurality of phase-shifted clock signals based on the clock signal and generating a phase-shifted training clock signal based on the clock signal, comparing the training data with a first reference voltage and a second reference voltage based on the phase-shifted clock signals and the phase-shifted training clock signal, determining whether phases of the phase-shifted clock signals lag or lead the phase-shifted training clock signal based on the comparison, outputting a phase adjusting signal based on the phase of the phase-shifted clock signals, and adjusting the clock signal based on the phase adjusting signal.

According to some example embodiments, the memory device and the memory controller may transmit and receive data through a high-bandwidth communication channel with improved reliability.

According to some example embodiments, the memory device and the memory controller may transmit and receive data with relatively lower power consumption through the high-bandwidth communication channel.

### BRIEF DESCRIPTION OF THE DRAWINGS

The above and other purposes and features of the present disclosure will become more apparent from the following detailed description, taken in conjunction with the accompanying drawings.

FIG. 1 is a block diagram illustrating a memory system according to some example embodiments.

FIG. 2 is a view illustrating the memory system of FIG. 1.

FIG. 3 is a view illustrating a duo-binary coding according to some example embodiments.

FIG. 4 is a block diagram illustrating a portion of a reception interface of a physical layer according to some example embodiments.

FIG. 5 is a block diagram illustrating a portion of a reception interface of a physical layer interface according to some example embodiments.

FIG. 6 is a block diagram illustrating a phase-shifted clock signal generating circuit of the reception interface of FIG. 5.

FIG. 7 is a waveform diagram illustrating clock signals generated by the phase-shifted clock signal generating circuit of FIG. 6.

FIG. 8 is a diagram illustrating a method of sampling training data based on the clock signals of FIG. 7.

FIGS. 9A, 9B, 9C, and 9D are diagrams illustrating an operation of a phase detecting circuit based on the training data of FIG. 8.

FIG. 10 is a block diagram illustrating a phase detecting circuit of FIG. 5.

FIG. 11 is a block diagram illustrating a portion of a transmission interface of a physical layer interface according to some example embodiments.

FIG. 12 is a circuit diagram illustrating a driver of FIG. 11.

FIG. 13 is a circuit diagram illustrating a first stage circuit of the driver of FIG. 12.

FIG. 14A is a circuit diagram illustrating an equalizer of FIG. 11.

FIG. 14B is a circuit diagram illustrating a second equalizer of the equalizer of FIG. 14A.

FIG. 14C is a diagram illustrating a variation in output voltage of the driver, which is caused by an operation of the equalizer.

FIG. 15 illustrating a flowchart of a method of training the clock signal of the memory device of FIG. 1, according to some example embodiments.

### DETAILED DESCRIPTION OF EXAMPLE EMBODIMENTS

Hereinafter, example embodiments of the present disclosure will be described more fully with reference to the accompanying drawings. However, the example embodiments may be implemented in different forms, and should not be interpreted to be limited to the example embodiments set forth herein. On the contrary, these example embodiments are provided so that the present disclosure will be thorough and complete, and will be fully conveyed to those skilled in the art that the present disclosure is not limited to the above example embodiments, and various modifications and amendments may be made without departing from the scope of the disclosure.

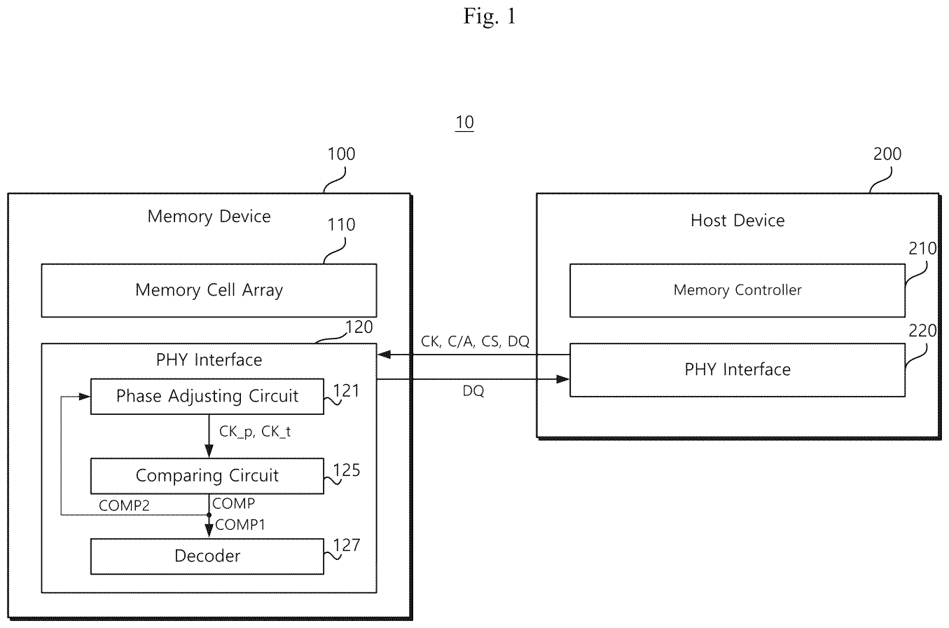

FIG. 1 is a block diagram illustrating a memory system 10, according to some example embodiments.

A physical layer (PHY) interface 120 of a memory device 100, according to some example embodiments, may generate a plurality of phase-shifted clock signals CK_p and a phase-shifted training clock signal CK_t using a clock signal CK received from a host device 200. The PHY interface 120 of the memory device 100 may train the phase-shifted clock signals CK_p using the phase-shifted training clock signal CK_t. The memory device 100 may sample data received through a plurality of communication channels with the same or similar length based on the trained phase-shifted clock signals CK_p.

Referring to FIG. 1, the memory system 10 may include the memory device 100 and the host device 200.

The host device 200 may include a memory controller 210 and a PHY interface 220.

The memory controller 210 may control an operation of the memory device 100 and may transmit the clock signal CK, a chip selecting signal CS, a command and address signal C/A, and/or a data signal DQ through the PHY interface 220. In addition or alternatively, the memory controller 210 may receive the data signal DQ from the memory device 100 through the PHY interface 220.

The host device 200 may include other logic circuits in addition to the memory controller 210 and the PHY interface 220.

According to some example embodiments, the host device 200 may be a system-on-chip, a central processing unit (CPU), or a graphics processing unit (GPU), however, the host device 200 is not limited thereto.

The memory device 100 may include a memory cell array 110 and the PHY interface 120.

The memory device 100 may receive the clock signal CK, the command and address signal C/A, the chip selecting signal CS, and/or the data signal DQ from the host device 200 through the PHY interface 120. In addition or alternatively, the memory device 100 may transmit the data signal DQ to the host device 200 through the PHY interface 120.

The memory device 100 may store the data signal DQ in the memory cell array 110 or may read out the data signal DQ from the memory cell array 110 based on a command applied thereto. A logic circuit of the memory device 100 may interpret the command.

The PHY interface 120 of the memory device 100 according to some example embodiments, may include a phase adjusting circuit 121, a comparing circuit 125, and/or a decoder (or decoder circuit) 127.

For the sake of explanation, the PHY interface 120 of the memory device 100 is described below and the description thereof is equally appliable to the PHY interface 220 of the host device 200.

The phase adjusting circuit 121 may generate the phase-shifted clock signals CK_p and the phase-shifted training clock signal CK_t based on the clock signal CK received from the host device 200.

According to some example embodiments, the phase-shifted clock signals CK_p may be a plurality of clock signals having different phases.

The comparing circuit 125 may compare the received data signal DQ with reference voltages based on the phase-shifted clock signals CK_p and the phase-shifted training clock signal CK_t and may output a comparison signal COMP.

According to some example embodiments, the reference voltages may be multiple. In some example embodiments, the reference voltages may include a first reference voltage and a second reference voltage. In some example embodiments, the comparison signal may indicate a result obtained by comparing the reference voltage with an input signal.

Since the comparison of the received data signal DQ may be performed based on each of the phase-shifted clock signals CK_p and the phase-shifted training clock signal CK_t, a plurality of comparison signals COMP may be generated.

Among the comparison signals COMP, a first comparison signal COMP1, which is included in the plurality of comparison signals COMP, may be transmitted to the decoder 127 and a second comparison signal COMP2, which is included in the plurality of comparison signals COMP, may be transmitted to the phase adjusting circuit 121. The first comparison signal COMP1 transmitted to the decoder 127 and the second comparison signal COMP2 transmitted to the phase adjusting circuit 121 may partially include similar comparison signals, as discussed below.

The decoder 127 may decode the received data signal DQ using the first comparison signal COMP1 among the plurality of comparison signals COMP.

According to some example embodiments, the received data signal DQ may be a duo-binary signal, and the decoder 127 may decode the data signal DQ based on a duo-binary.

The phase adjusting circuit 121 may determine a degree of delay of the clock signal CK using the phase-shifted training clock signal CK_t.

In some example embodiments, the phase adjusting circuit 121 may determine the degree of delay of the clock signal CK based on the second comparison signal COMP2 provided from the comparing circuit 125. The second comparison signal COMP2 may include comparison signals obtained by the comparing circuit 125 that compares the data signal DQ with each of the first reference voltage and the second reference voltage based on the phase-shifted training clock signal CK_t. The second comparison signal COMP2 may include comparison signals obtained by the comparing circuit 125 that compares the data signal DQ with each of the first reference voltage and the second reference voltage based on some clock signals of the phase-shifted clock signals CK_p.

Phases of the phase-shifted clock signals CK_p may be adjusted based on the delayed clock signal, and as a result, the data signal DQ received from the host device 200 may be sampled and decoded with relatively higher accuracy. The comparison signal based on the phase-shifted training clock signal CK_t may not be input to the decoder 127.

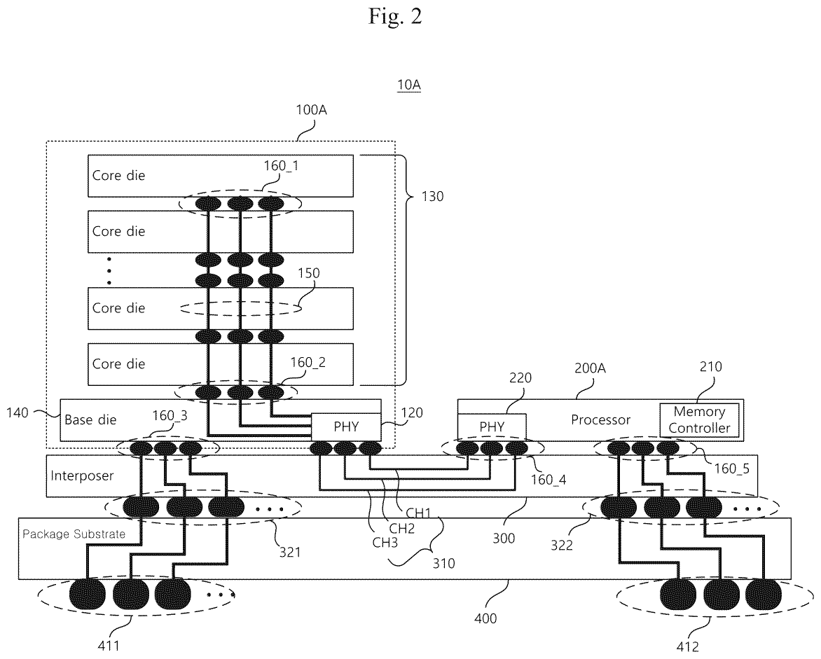

FIG. 2 illustrates the memory system 10 of FIG. 1 according to some example embodiments. FIG. 2 illustrates the memory system 10 of FIG. 1, which is implemented in a system-in-package 10A. Hereinafter, the system-in-package 10A will be described with reference to FIGS. 1 and 2.

Referring to FIG. 2, the system-in-package 10A may include a memory device 100A implemented as a high bandwidth memory (HBM) device, a processor 200A, an interposer 300, and a package substrate 400.

The memory device 100A may include a plurality of core dies 130 and a base die 140. The base die 140 may be referred to as a logic die or a buffer die.

The core dies 130 and the base die 140 of the memory device 100A may be stacked on the interposer 300. The memory device 100A and the processor 200A may be stacked on the interposer 300, and the interposer 300 may be stacked on the package substrate 400. The core die 130 may be disposed on the base die 140.

The processor 200A may be a system-on-chip, a central processing unit, or a graphics processing unit. The type of the processor 200A is not limited to any particular type of processor in the example embodiments.

The core die 130 may be electrically connected to the base die 140. The core die 130 may include a conductive member to connect the core dies 130 to each other. The core die 130 and the base die 140 may communicate with each other through a conductive member. In some example embodiments, the core dies 130 may be electrically connected to each other through a through-silicon via (TSV) 150 and micro-bumps 160_1 and 160_2. Each core die 130 may include at least one via formed to vertically penetrate therethrough.

Each of the core dies 130 may include at least one memory core. The memory core may include a memory cell array to store data, a row decoder, a column decoder, and a sense amplifier.

Each of the core dies 130 may further include a control logic electrically connected to the base die 140 and performing a read/write operation in the core die 130. The control logic of each of the core die 130 may be electrically connected to the base die 140, and the base die 140 and each of the core dies 130 may transmit and receive various control signals and data signals.

The base die 140 may be connected to the interposer 300 through a micro-bump 160_3. The base die 140 may communicate with or receive power from an external source of a package through the micro-bump 160_3, an internal wiring of the interposer 300, a bump 321, an internal wiring of the package substrate 400, and a ball grid 411.

The base die 140 may provide the data signal DQ, the command signal and address signal C/A, and the chip selecting signal CS of FIG. 1, which are received from the memory controller 210 of the processor 200A through communication channels 310 (CH1, CH2, and CH3), to the core die 130. The base die 140 may provide the data signal DQ received from the core die 130 to the memory controller 210 through the communication channels CH1, CH2, and CH3.

The memory device 100A and the processor 200A may communicate with each other through the PHY interfaces 120 and 220.

The processor 200A may be connected to the interposer 300 through a micro-bump 160_5. The processor 200A may communicate with or receive power from the external source of the package through the micro-bump 160_5, the internal wiring of the interposer 300, a bump 322, the internal wiring of the package substrate 400, and a ball grid 412.

Referring to FIG. 2, the memory device 100A and the processor 200A may transmit and receive electrical signals to and from each other through their respective PHY interfaces 120 and 220, and the communication channels 310 (CH1, CH2, and CH3). The communication channels 310 (CH1, CH2, and CH3) may have different path lengths from each other.

In some example embodiments, FIG. 2 illustrates that the path length of the first communication channel CH1 is the shortest, while the path length of the third communication channel CH3 is the longest. FIG. 2 illustrates one example of each of the communication channels 310 (CH1, CH2, and CH3), and the number of communication channels between the memory device 100A and the processor 200A may be greater (or less than) than the number shown in FIG. 2.

The PHY interface 120 of the memory device 100A, according to some example embodiments, may generate the phase-shifted clock signals CK_p and the phase-shifted training clock signal CK_t of FIG. 1 using the clock signal received from the processor 200A.

The PHY interface 120 of the memory device 100A may sample the data received through the communication channels with the same path length based on the trained phase-shifted clock signals CK_p.

In some example embodiments, FIG. 2 illustrates a case where there is one first communication channel CH1, however, there may be multiple communication channels having the same path length as the first communication channel CH1. The PHY interface 120 may sample the data received through the first communication channel CH1 and the communication channels with the same path length as the first communication channel CH1 using the phase-shifted clock signals CK_p that are trained identically.

Similarly, the PHY interface 120 may sample the data received through the second communication channel CH2 and the communication channels with the same path length as the second communication channel CH2 using the phase-shifted clock signals CK_p that are trained similarly (e.g., identically). The phase-shifted clock signals CK_p used in sampling the data respectively received through the first communication channel CH1 and the second communication channel CH2 may be different from each other.

Accordingly, in some sampling methods, clock signal delay circuits may be used for each of the communication channels 310 (CH1, CH2, and CH3). In addition, clock signal delay circuits may be used for the communication channels having the same path length as the communication channels 310 (CH1, CH2, and CH3). The PHY interface 120 may sample the data received through the communication channels with the same path length using the phase-shifted clock signals CK_p that are similarly trained. As a result, circuits of the PHY interface 120 may be simplified, and a power consumption may be reduced.

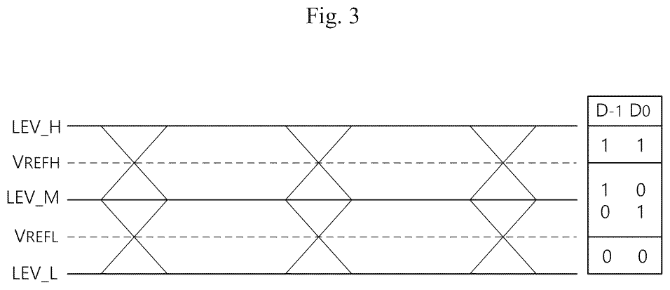

FIG. 3 is a view illustrating a duo-binary coding, according to some example embodiments. The duo-binary coding described with reference to FIG. 3 may be used in the PHY interfaces 120 and 220 of the memory device 100 and the host device 200 of FIG. 1.

Referring to FIG. 3, an eye diagram corresponding to 2 UI (unit intervals) of FIG. 3 is shown. The eye diagram may be referred to as an eye pattern.

The data signal DQ of FIG. 1, which is received through the communication channel, may be a duo-binary signal. The duo-binary signal may have three voltage levels LEV_H, LEV_M, and LEV_L. In some example embodiments, the duo-binary signal may be a signal having a high level LEV_H, a signal having a middle level LEV_M, or a signal having a low level LEV_L in a 1 UI.

The PHY interface 120 of the memory device 100 of FIG. 1 may sample the duo-binary signal based on the clock signal, and the comparing circuit 125 may compare the sampled voltage value with each of reference voltages VREFH and VREFL and may output the compared results as the comparison signals. The decoder 127 may perform a duo-binary decoding on the received data using the comparison signals. Similarly, the PHY interface 220 of the host device 200 of FIG. 1 may perform a duo-binary encoding on the data.

The memory device 100 and the host device 200 of FIG. 1 may transmit the duo-binary signal by utilizing states of two consecutive bits.

The duo-binary coding may be implemented in various ways. In some example embodiments, referring to FIG. 3, a previous data bit D-1 of the duo-binary signal may be compared with a current data bit D0 of the duo-binary signal, and the duo-binary signal may be encoded or decoded to the high level LEV_H when the previous data bit D-1 and the current data bit D0 are both “1,” may be encoded or decoded to the low level LEV_L when the previous data bit D-1 and the current data bit D0 are both “0,” and may be encoded or decoded to the middle level LEV_M when the previous data bit D-1 and the current data bit D0 are changed (“10” or “01”). For the sake of explanation, example embodiments are described assuming that the duo-binary signal is encoded or decoded in the above described manner.

The duo-binary coding may be implemented differently from that described with reference to FIG. 3. In some example embodiments, different from FIG. 3, the duo-binary signal may be encoded or decoded to the middle level LEV_M when the previous data bit D-1 is equal to the current data bit D0, and may be encoded or decoded to the high level LEV_H or the low level LEV_L when the previous data bit D-1 is different from the current data bit D0. The duo-binary signal may be encoded or decoded to the low level LEV_L when the previous data bit D-1 is “1” and the current data bit D0 is “0” and may be encoded or decoded to the high level LEV_H when the previous data bit is “0” and the current data bit is “1”. It will be understood that the method of duo-binary coding may not be limited to any specific method of duo-binary coding.

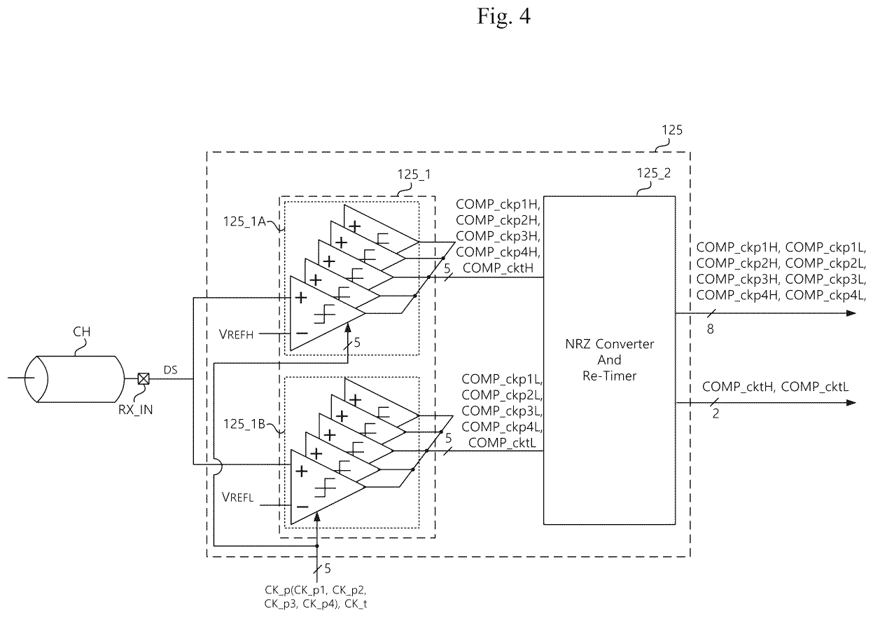

FIG. 4 is a block diagram illustrating a portion of a reception interface of a physical layer according to some example embodiments. A comparing circuit 125 of FIG. 4 may correspond to the comparing circuit 125 of the PHY interface 120 of FIG. 1. The comparing circuit 125 of FIG. 4 may also be used in the PHY interface 220 of the host device 200 of FIG. 1. The comparing circuit 125 will be described with reference to FIGS. 1 and 4.

Referring to FIG. 4, the comparing circuit 125 may include at least one comparator 125_1, a non-return-to-zero (NRZ) converter and re-timer 125_2. According to some example embodiments, the comparing circuit 125 may not include the NRZ converter and re-timer 125_2.

Each of the comparators 125_1 may receive a duo-binary signal DS and one of reference voltages VREFH and VREFL. In some example embodiments, a first comparator 125_1A in the at least one comparator 125_1 may receive the duo-binary signal DS and a first reference voltage VREFH, and a second comparator 125_1B in the at least one comparator 125_1 may receive the duo-binary signal DS and a second reference voltage VREFL.

Each of the comparators 125_1 may compare the duo-binary signal DS with the reference voltages VREFH and VREFL based on a plurality of phase-shifted clock signals CK_p and a phase-shifted training clock signal CK_t. In some example embodiments, the duo-binary signal DS may be compared with the reference voltages VREFH and VREFL at every falling edge or rising edge of the phase-shifted clock signals CK_p and the phase-shifted training clock signal CK_t.

The phase-shifted clock signals CK_p may include various clock signals. In some example embodiments, the phase-shifted clock signals CK_p may include a first phase-shifted clock signal CK_p1, a second phase-shifted clock signal CK_p2, a third phase-shifted clock signal CK_p3, and a fourth phase-shifted clock signal CK_p4.

It will be understood that the phase-shifted clock signals CK_p are not limited to four phase-shifted clock signals having different phases. In some example embodiments, the phase-shifted clock signals CK_p may include less than four or more than four phase-shifted clock signals.

Each of the comparators 125_1 may compare the duo-binary signal DS with the reference voltages VREFH and VREFL based on the first phase-shifted clock signal CK_p1, the second phase-shifted clock signal CK_p2, the third phase-shifted clock signal CK_p3, the fourth phase-shifted clock signal CK_p4, and the phase-shifted training clock signal CK_t.

Accordingly, the first comparator 125_1A may output a first high comparison signal COMP_ckp1H obtained by comparing the duo-binary signal DS with the first reference voltage VREFH based on the first phase-shifted clock signal CK_p1, a second high comparison signal COMP_ckp2H obtained by comparing the duo-binary signal DS with the first reference voltage VREFH based on the second phase-shifted clock signal CK_p2, a third high comparison signal COMP_ckp3H obtained by comparing the duo-binary signal DS with the first reference voltage VREFH based on the third phase-shifted clock signal CK_p3, a fourth high comparison signal COMP_ckp4H obtained by comparing the duo-binary signal DS with the first reference voltage VREFH based on the fourth phase-shifted clock signal CK_p4, and a training high comparison signal COMP_cktH obtained by comparing the duo-binary signal DS with the first reference voltage VREFH based on the phase-shifted training clock signal CK_t.

Similarly, the second comparator 125_1B may output a first low comparison signal COMP_ckp1L, a second low comparison signal COMP_ckp2L, a third low comparison signal COMP_ckp3L, a fourth low comparison signal COMP_ckp4L, and a training low comparison signal COMP_cktL.

The NRZ converter and re-timer 125_2 may convert the comparison signals into an NRZ signal and may synchronize a start timing of the comparison signals when the comparison signals of the comparator 125_1 are a return-to-zero (RZ) signal. The NRZ converter and re-timer 125_2 may output the synchronized comparison signals COMP_ckp1H, COMP_ckp2H, COMP_ckp3H, COMP_ckp4H, COMP_ckp1L, COMP_ckp2L, COMP_ckp3L, COMP_ckp4L, COMP_cktH, and COMP_cktL.

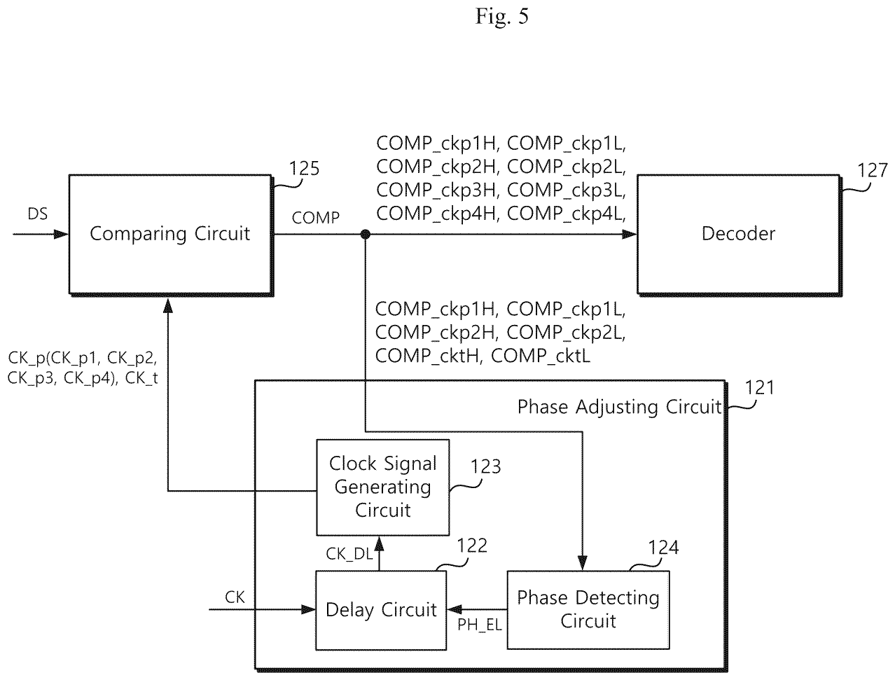

FIG. 5 is a block diagram illustrating a portion of a reception interface of a physical layer interface according to some example embodiments. FIG. 5 illustrates a phase adjusting circuit 121, a comparing circuit 125, and a decoder 127. The phase adjusting circuit 121, the comparing circuit 125, and the decoder 127 of FIG. 5 may correspond to the phase adjusting circuit 121, the comparing circuit 125, and the decoder 127 of FIG. 1, respectively. The comparing circuit 125 of FIG. 5 may correspond to the comparing circuit 125 of FIG. 4. The phase adjusting circuit 121, the comparing circuit 125, and the decoder 127 will be described with reference to FIGS. 1, 4, and 5.

Referring to FIG. 5, the phase adjusting circuit 121 may include a delay circuit 122, a clock signal generating circuit 123, and a phase detecting circuit 124.

The delay circuit 122 may receive a clock signal CK and may delay the clock signal CK based on a phase-delay control signal PH_EL output from the phase detecting circuit 124. The delay circuit 122 may output a clock signal CK_DL obtained by delaying the clock signal CK. The delay circuit 122 may include a plurality of delay elements.

The clock signal generating circuit 123 may generate a plurality of phase-shifted clock signals CK_p and a phase-shifted training clock signal CK_t based on the delayed clock signal CK_DL. The phase-shifted clock signals CK_p may include various clock signals, and, in some example embodiments, the phase-shifted clock signals CK_p may include a first phase-shifted clock signal CK_p1, a second phase-shifted clock signal CK_p2, a third phase-shifted clock signal CK_p3, and a fourth phase-shifted clock signal CK_p4.

The comparing circuit 125 may compare a duo-binary signal DS with reference voltages VREFH and VREFL based on the phase-shifted clock signals CK_p and the phase-shifted training clock signal CK_t. The comparing circuit 125 may output a comparison signal COMP. The comparison signal COMP may include a plurality of comparison signals COMP_ckp1H, COMP_ckp2H, COMP_ckp3H, COMP_ckp4H, COMP_ckp1L, COMP_ckp2L, COMP_ckp3L, COMP_ckp4L, COMP_cktH, and COMP_cktL.

First comparison signals COMP_ckp1H, COMP_ckp2H, COMP_ckp3H, COMP_ckp4H, COMP_ckp1L, COMP_ckp2L, COMP_ckp3L, and COMP_ckp4L that are a portion of the comparison signal COMP may be transmitted to the decoder 127. The decoder 127 may perform a duo-binary decoding.

The comparison signals COMP_cktH and COMP_cktL of the comparison signal COMP based on the phase-shifted training clock signal CK_t may not be transmitted to the decoder 127 and the comparison signals COMP_cktH and COMP_cktL may not be used in decoding of the duo-binary signal DS.

Second comparison signals COMP_ckp1H, COMP_ckp2H, COMP_ckp1L, COMP_ckp2L, COMP_cktH, and COMP_cktL that are a portion of the comparison signal COMP may be transmitted to the phase adjusting circuit 121. Only a portion of the comparison signals among the comparison signals based on the phase-shifted clock signals CK_p may be transmitted to the phase adjusting circuit 121.

The comparison signals COMP_cktH and COMP_cktL based on the phase-shifted training clock signal CK_t among the comparison signals COMP may be transmitted to the phase adjusting circuit 121 and thus may be used in training the clock signal CK.

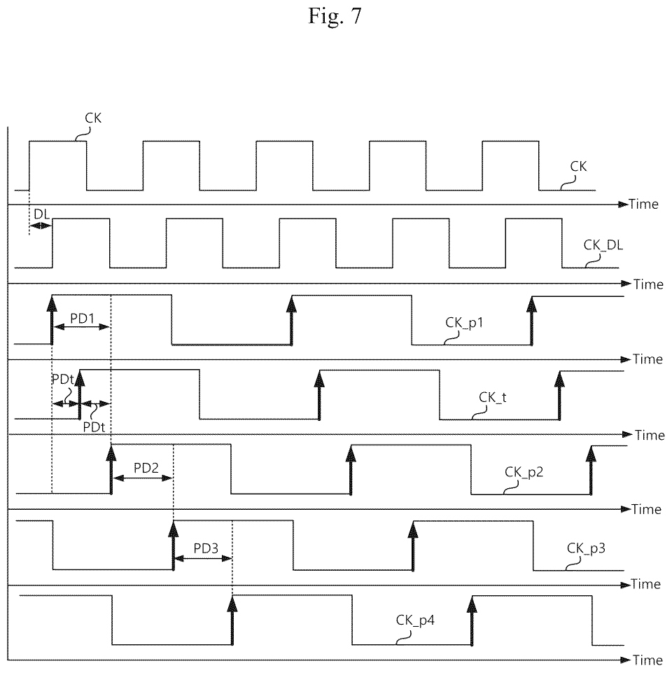

In some example embodiments, the comparison signals transmitted to the phase adjusting circuit 121 may be comparison signals COMP_ckp1H, COMP_ckp2H, COMP_ckp1L, and COMP_ckp2L based on the first phase-shifted clock signal CK_p1 and the second phase-shifted clock signal CK_p2 among the phase-shifted clock signals CK_p. A phase of the phase-shifted training clock signal CK_t may be located between a phase of the first phase-shifted clock signal CK_p1 and a phase of the second phase-shifted clock signal CK_p2. The phase of the phase-shifted training clock signal CK_t may lag behind the phase of the first phase-shifted clock signal CK_p1 and may lead the phase of the second phase-shifted clock signal CK_p2. A difference in phase between the phase-shifted training clock signal CK_t and the first phase-shifted clock signal CK_p1 may be smaller than a difference in phase between the phase-shifted clock signals CK_p. This will be described in detail later with reference to FIG. 7.

The phase detecting circuit 124 may determine whether the phase-shifted clock signals CK_p and the phase-shifted training clock signal CK_t provided to the comparing circuit 125 are lagging or leading the clock signal CK based on the second comparison signals COMP_ckp1H, COMP_ckp2H, COMP_ckp1L, COMP_ckp2L, COMP_cktH, and COMP_cktL. The lagging or leading of the delayed clock signal CK_DL may thus be determined.

In the case where the delayed clock signal CK_DL is lagging, the phase adjusting circuit 121 may transmit the phase-delay control signal PH_EL, which instructs an increase in the delay amount, to the delay circuit 122. In the case where the delayed clock signal CK_DL is leading, the phase adjusting circuit 121 may transmit the phase-delay control signal PH_EL that instructs the increase in the delay amount or the phase-delay control signal PH_EL terminating the training of the clock signal CK to the delay circuit 122.

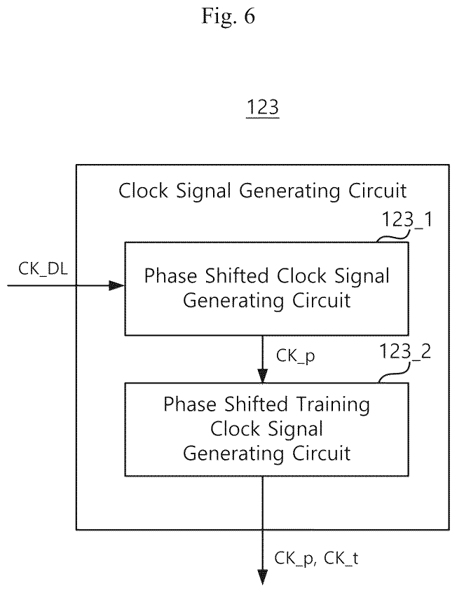

FIG. 6 is a block diagram illustrating the clock signal generating circuit 123 of the reception interface of FIG. 5. FIG. 7 is a waveform diagram illustrating the clock signals CK_p1, CK_p2, CK_p3, CK_p4, and CK_t generated by the clock signal generating circuit 123 of FIG. 6. The clock signal generating circuit 123 will be described with reference to FIGS. 6 and 7.

When describing the clock signal generating circuit 123 with reference to FIGS. 6 and 7, for the sake of discussion, it assumed that the phase-shifted clock signals CK_p include four phase-shifted clock signals CK_p1, CK_p2, CK_p3, and CK_p4. However, the phase-shifted clock signals CK_p may include fewer than four or more than four phase-shifted clock signals, as described above.

Referring to FIG. 6, the clock signal generating circuit 123 may output the phase-shifted clock signals CK_p and the phase-shifted training clock signal CK_t.

The phase adjusting circuit 121 may include a phase-shifted clock signal generating circuit 123_1 and a phase-shifted training clock signal generating circuit 123_2.

In some example embodiments described with reference to FIGS. 6 and 7, the clock signals CK_p1, CK_p2, CK_p3, CK_p4, and CK_t are generated based on the delayed clock signal CK_DL. However, the clock signal generating circuit 123 may generate the clock signals CK_p1, CK_p2, CK_p3, CK_p4, and CK_t based on the clock signal CK. In some example embodiments, the delayed clock signal CK_DL provided to the clock signal generating circuit 123 right after the clock signal CK is received may be substantially the same as the clock signal CK and thus the delay amount DL may be “0”.

Referring to FIGS. 6 and 7, the phase-shifted clock signal generating circuit 123_1 may generate the first phase-shifted clock signal CK_p1, the second phase-shifted clock signal CK_p2 having a first phase difference PD1 with respect to the first phase-shifted clock signal CK_p1, the third phase-shifted clock signal CK_p3 having a second phase difference PD2 with respect to the second phase-shifted clock signal CK_p2, and the fourth phase-shifted clock signal CK_p4 having a third phase difference PD3 with respect to the third phase-shifted clock signal CK_p3.

The phase-shifted clock signals CK_p (CK_p1, CK_p2, CK_p3, CK_p4) may have substantially the same phase difference. In some example embodiments, the first phase difference PD1, the second phase difference PD2, and the third phase difference PD3 may be the same as each other. Each of the first phase difference PD1, the second phase difference PD2, and the third phase difference PD3 may be 90 degrees (or about 90 degrees).

Accordingly, the first phase-shifted clock signal CK_p1 may have the same phase as the delayed clock signal CK_DL. The second phase-shifted clock signal CK_p2 may lag the delayed clock signal CK_DL by about 90 degrees, the third phase-shifted clock signal CK_p3 may lag the clock signal CK_DL by about 180 degrees, and the fourth phase-shifted clock signal CK_p4 may lag the clock signal CK_DL by about 270 degrees.

The phase-shifted training clock signal CK_t may lag the first phase-shifted clock signal CK_p1 by a training phase difference PDt and may lead the second phase-shifted clock signal CK_p2 by the training phase difference PDt. The phase of the phase-shifted training clock signal CK_t may have the same or similar phase difference PDt with respect to the phase of the first phase-shifted clock signal CK_p1 and the phase of the second phase-shifted clock signal CK_p2.

FIG. 7 illustrates the phase-shifted training clock signal CK_t with the phase located between the phase of the first phase-shifted clock signal CK_p1 and the phase of the second phase-shifted clock signal CK_p2.

However, according to some example embodiments, the phase of the phase-shifted training clock signal CK_t may be located between the phase of the second phase-shifted clock signal CK_p2 and the phase of the third phase-shifted clock signal CK_p3. In this case, the second comparison signals transmitted from the comparing circuit 125 to the phase adjusting circuit 121 in FIG. 5 may include the comparison signals COMP_ckp2H, COMP_ckp3H, COMP_ckp2L, and COMP_ckp3L based on the second phase-shifted clock signal CK_p2 and the third phase-shifted clock signal CK_p3.

According to some example embodiments, the phase of the phase-shifted training clock signal CK_t may be located between the phase of the third phase-shifted clock signal CK_p3 and the phase of the fourth phase-shifted clock signal CK_p4. In this case, the second comparison signals transmitted from the comparing circuit 125 to the phase adjusting circuit 121 in FIG. 5 may include the comparison signals COMP_ckp3H, COMP_ckp4H, COMP_ckp3L, and COMP_ckp4L based on the third phase-shifted clock signal CK_p3 and the fourth phase-shifted clock signal CK_p4.

That is, the phase of the phase-shifted training clock signal CK_t may be located between the phase-shifted clock signals having the phases adjacent (e.g., immediately adjacent) to each other among the phase-shifted clock signals CK_p (CK_p1, CK_p2, CK_p3, CK_p4).

FIG. 7 illustrates that the comparison of the duo-binary signal is performed at the rising edge of the phase-shifted clock signals CK_P, however, in some example embodiments, the comparison of the duo-binary signal may be performed at the falling edge of the phase-shifted clock signals CK_p.

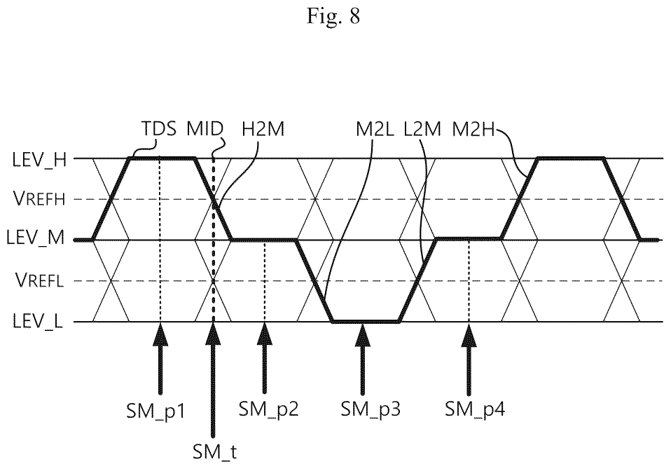

FIG. 8 is a diagram illustrating a method of sampling training data based on the clock signals of FIG. 7. The training data may be transmitted as a duo-binary signal. Training duo-binary signal TDS may be a duo-binary signal coded from the training data. The sampling method described herein assumes that a training duo-binary signal TDS has the waveform of FIG. 8.

The training duo-binary signal TDS of FIG. 8 may be transmitted to the memory device 100 from the host device 200 of FIG. 1. The comparing circuit 125 of FIG. 5 may perform the comparing of the training duo-binary signal TDS based on the clock signals CK_p and CK_t of FIG. 7.

Referring to FIG. 8, the training duo-binary signal TDS may include a signal with a high level LEV_H, a signal with a middle level LEV_M, and a signal with a low level LEV_L.

The training duo-binary signal TDS may include a first transition signal H2M transited from the signal with the high level LEV_H to the signal with the middle level LEV_M, a second transition signal M2L transited from the signal with the middle level LEV_M to the signal with the low level LEV_L, a third transition signal L2M transited from the signal with the low level LEV_L to the signal with the middle level LEV_M, and a fourth transition signal M2H transited from the signal with the middle level LEV_M to the signal with the high level LEV_H.

Accordingly, the signal with the high level LEV_H may be continuous with the signal with the middle level LEV_M, and the signal with the low level LEV_L may be continuous with the signal with the middle level LEV_M. The signal with the middle level LEV_M may be located between the signal with the high level LEV_H and the signal with the low level LEV_L.

Although FIG. 8 illustrates the training duo-binary signal TDS generated from encoded data of “0011” bits, the training duo-binary signal TDS may also be generated from other bits. The training duo-binary signal TDS may be any duo-binary signal which includes the signal with the high level LEV_H, the signal with the middle level LEV_M, the signal with the low level LEV_L, the first transition signal H2M, the second transition signal M2L, the third transition signal L2M, and the fourth transition signal M2H.

Referring to FIG. 8, the comparing circuit 125 of FIG. 5 may perform the sampling and comparing operations at four points SM_p1, SM_p2, SM_p3, and SM_p4 of the training duo-binary signal TDS based on the phase-shifted clock signals CK_p1, CK_p2, CK_p3, and CK_p4 of FIG. 7. In addition, the comparing circuit 125 may perform the sampling and comparing operations at one point SM_t of the training duo-binary signal TDS based on the phase-shifted training clock signal CK_t.

In the case where the phase-shifted clock signals CK_p (CK_p1, CK_p2, CK_p3, CK_p4) are trained to the training duo-binary signal TDS, the comparing circuit 125 of FIG. 5 may sample (e.g., with a relatively improved precision) a midpoint of the first transition signal H2M based on the phase-shifted training clock signal CK_t. Therefore, the training duo-binary signal TDS sampled at the point SM_t may be same or similar in some respects to the first reference voltage VREFH.

Accordingly, the phase detecting circuit 124 of FIG. 5 may determine whether an operation of delaying the phase-shifted clock signals CK_p is to be performed based on a comparison signal of the training duo-binary signal TDS sampled at the point SM_t and the first reference voltage VREFH.

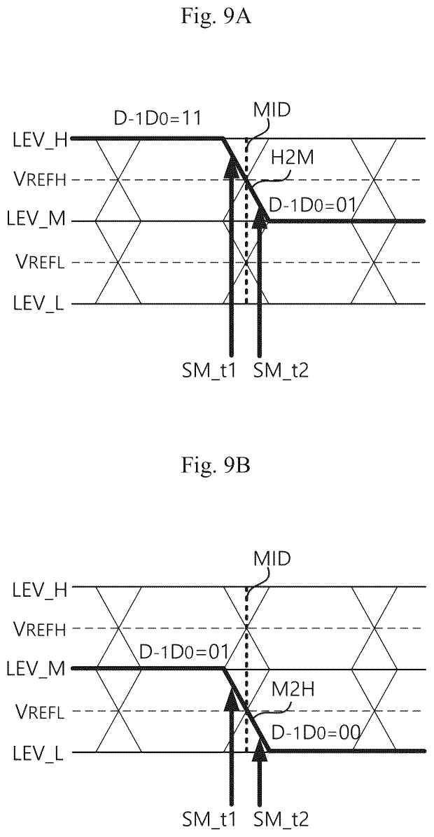

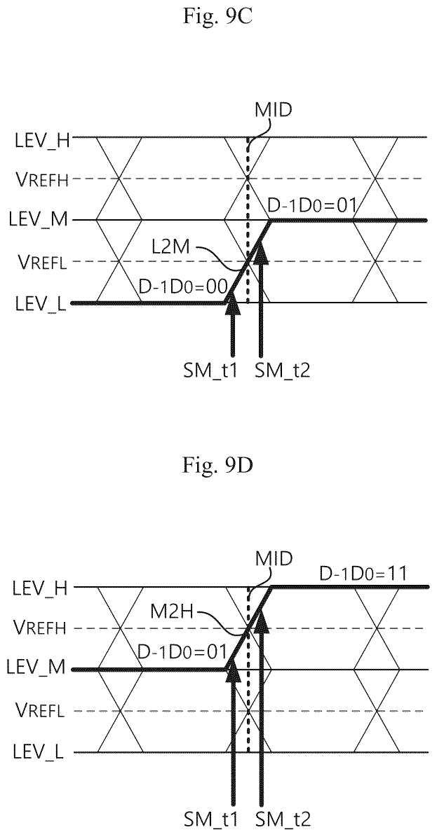

FIGS. 9A to 9D are diagrams illustrating an operation of the phase detecting circuit 124 based on the training duo-binary signal TDS of FIG. 8. The operation described with reference to FIGS. 5 and 9A to 9D may be performed in the phase detecting circuit 124 of FIG. 5.

FIGS. 9A to 9D illustrate the operation of the phase detecting circuit 124 of FIG. 5 when the sampling points of the phase-shifted training clock signal CK_t are located at the first transition signal H2M, the second transition signal M2L, the third transition signal L2M, and the fourth transition signal M2H, respectively.

Referring to FIG. 9A, the phase detecting circuit 124 of FIG. 5 may determine whether the sampling point based on the phase-shifted training clock signal CK_t is a first point SM_t1 preceding a midpoint MID of the first transition signal H2M or a second point SM_t2 following the midpoint MID of the first transition signal H2M using the comparison signals, e.g., COMP_cktH and COMP_cktL of FIG. 5, based on the phase-shifted training clock signal CK_t.

The sampling point based on the phase-shifted training clock signal CK_t may be the first point SM_t1, which is earlier than the midpoint MID of the first transition signal H2M. In this case, the phase detecting circuit 124 of FIG. 5 may output the delay control signal PH_EL instructing that the phase-shifted clock signals CK_p be delayed.

On the contrary, the sampling point based on the phase-shifted training clock signal CK_t may be the second point SM_t2, which is later than the midpoint MID of the first transition signal H2M. In this case, the phase detecting circuit 124 of FIG. 5 may output the delay control signal PH_EL instructing that any additional delay of the phase-shifted clock signals CK_p be stopped or may output the delay control signal PH_EL instructing that the phase-shifted clock signals CK_p be advanced.

Similar to FIG. 9A, in a case where the sampling points based on the phase-shifted training clock signal CK_t are respectively the first points SM_t1 preceding the midpoint MID at the second transition signal M2L of FIG. 9B, the third transition signal L2M of FIG. 9C, and the fourth transition signal M2H of FIG. 9D, the phase detecting circuit 124 of FIG. 5 may output the delay control signal PH_EL instructing that the phase-shifted clock signals CK_p be delayed.

Similarly, in the case where the sampling points based on the phase-shifted training clock signal CK_t are respectively the first points SM_t1 in advance of the midpoint MID at the second transition signal M2L of FIG. 9B, the third transition signal L2M of FIG. 9C, and the fourth transition signal M2H of FIG. 9D, the phase detecting circuit 124 of FIG. 5 may output the delay control signal PH_EL instructing that any additional delay of the phase-shifted clock signals CK_p be stopped or may output the delay control signal PH_EL instructing that the phase-shifted clock signals CK_p be advanced.

The phase detecting circuit 124 of FIG. 5 may determine which transition stage of the training duo-binary signal TDS the sampling point based on the phase-shifted training clock signal CK_t corresponds to using the comparison signals COMP_ckp1H and COMP_ckp1L based on the first phase-shifted clock signal CK_p1 and the comparison signals COMP_ckp2H and COMP_ckp2L based on the second phase-shifted clock signal CK_p2.

In some example embodiments, the phase detecting circuit 124 may determine which signal the sampling point based on the phase-shifted training clock signal CK_t corresponds to among the first transition signal H2M of FIG. 9A, the second transition signal M2L of FIG. 9B, the third transition signal L2M of FIG. 9C, and the fourth transition signal M2H of FIG. 9D. For instance, when the comparison signals COMP_ckp1H and COMP_ckp1L based on the first phase-shifted clock signal CK_p1 are “11” and the comparison signals COMP_ckp2H and COMP_ckp2L based on the second phase-shifted clock signal CK_p2 are “01”, the phase detecting circuit 124 may determine that the sampling point based on the phase-shifted training clock signal CK_t corresponds to the first transition signal H2M of FIG. 9A.

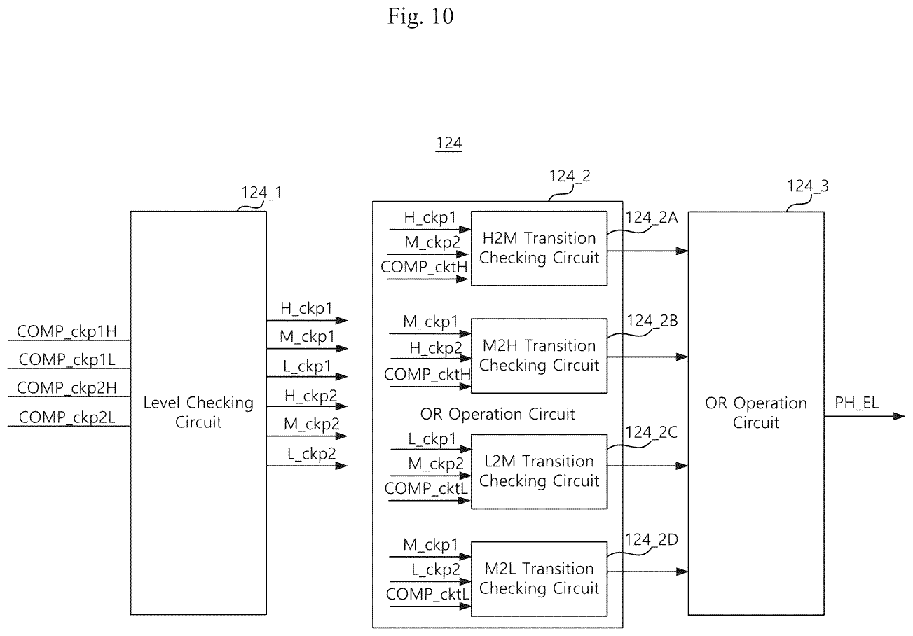

FIG. 10 is a block diagram illustrating the phase detecting circuit 124 of FIG. 5. The phase detecting circuit 124 will be described with reference to FIGS. 5 and 10.

The phase detecting circuit 124 may include a level checking circuit 124_1, a transition checking circuit 124_2, and an OR operation circuit 124_3.

The level checking circuit 124_1 may receive the comparison signals COMP_ckp1H, COMP_ckp1L, COMP_ckp2H, and COMP_ckp2L based on the first phase-shifted clock signal CK_p1 and the second phase-shifted clock signal CK_p2 and may output checking signals H_ckp1, M_ckp1, L_ckp1, H_ckp2, M_ckp2, and L_ckp2.

The level checking circuit 124_1 may output the signal H_ckp1 indicating whether the point sampled by the first phase-shifted clock signal CK_p1 in the training duo-binary signal TDS is the signal with the high level LEV_H, the signal M_ckp1 indicating whether the point is the signal with the middle level LEV_M, and the signal L_ckp1 indicating whether the point is the signal with the low level LEV_L.

Similarly, the level checking circuit 124_1 may output the signal H_ckp2 indicating whether the point sampled by the second phase-shifted clock signal CK_p2 in the training duo-binary signal TDS is the signal with the high level LEV_H, the signal M_ckp2 indicating whether the point is the signal with the middle level LEV_M, and the signal L_ckp2 that checks the point is the signal with the low level LEV_L.

The transition checking circuit 124_2 may include circuits 124_2A, 124_2B, 124_2C, and 124_2D that respectively determine the location of the sampling point at a transition signal (or transition stage) based on the phase-shifted training clock signal CK_t.

In some example embodiments, the transition checking circuit 124_2 may include a first transition checking circuit 124_2A that checks whether a sampling point based on the phase-shifted training clock signal CK_t is the first transition signal H2M, a second transition checking circuit 124_2B that checks whether the sampling point is the second transition signal M2L, a third transition checking circuit 124_2C that checks whether the sampling point is the third transition signal L2M, and a fourth transition checking circuit 124_2D that checks whether the sampling point is the fourth transition signal M2H.

The first transition checking circuit 124_2A may receive the signal H_ckp1 indicating whether the point sampled by the first phase-shifted clock signal CK_p1 in the training duo-binary signal TDS is the signal with the high level LEV_H, the signal M_ckp2 indicating whether the point sampled by the second phase-shifted clock signal CK_p2 in the training duo-binary signal TDS is the middle level LEV_M, and the comparison signal COMP_cktH obtained by comparing the duo-binary signal DS with the first reference voltage VREFH based on the phase-shifted training clock signal CK_t.

When each of the signal H_ckp1, the signal M_ckp2, and the comparison signal COMP_cktH is “1”, the first transition checking circuit 124_2A may output a value of “1”. The first transition checking circuit 124_2A may determine that the sampling point based on the training clock signal CK_t is the first transition signal H2M and the phase-shifted clock signals CK_p are leading relative to the training duo-binary signal TDS. Accordingly, the first transition checking circuit 124_2A may output a value of “0” when one of the signal H_ckp1, the signal M_ckp2, and the comparison signal COMP_cktH is “0”.

The second transition checking circuit 124_2B, the third transition checking circuit 124_2C, and the fourth transition checking circuit 124_2D may operate in a manner same as or similar in some respects to operation of the first transition checking circuit 124_2A and a repeat discussion thereof is omitted herein for the sake of brevity.

When one of the first transition checking circuit 124_2A, the second transition checking circuit 124_2B, the third transition checking circuit 124_2C, and the fourth transition checking circuit 124_2D outputs “1”, the OR operation circuit 124_3 may determine that the phase-shifted clock signals CK_p are leading relative to the training duo-binary signal TDS and may output the control signal PH_EL to delay the phase-shifted clock signals CK_p.

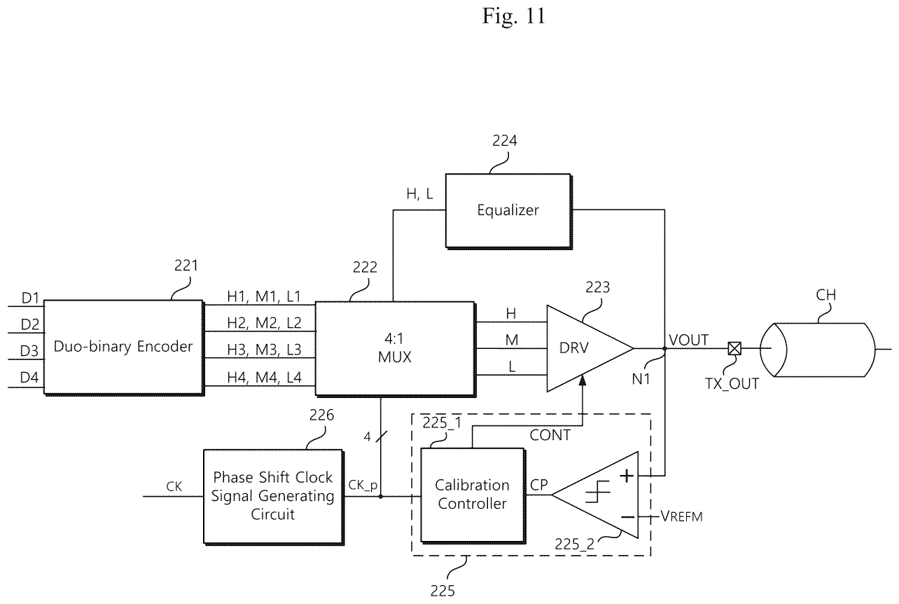

FIG. 11 is a block diagram illustrating a portion of a transmission interface of a physical layer interface according to some example embodiments. The transmission interface of FIG. 11 may correspond to the PHY interfaces 120 and 220 of FIG. 1.

FIG. 11 illustrates the transmission interface of the PHY interface 220 of the host device 200 of FIG. 1. However, the PHY interface 120 of the memory device 100 of FIG. 1 may be the same as or similar in some respects to the transmission interface of FIG. 11.

Referring to FIG. 11, the PHY interface 220 may include a duo-binary encoder 221, a multiplexer 222, a driver 223, an equalizer 224, a calibration circuit 225, and a phase-shifted clock signal generating circuit 226.

The duo-binary encoder 221 may output signals H1, M1, L1, H2, M2, L2, H3, M3, L3, H4, M4, and L4 obtained based on duo-binary encoding data D1, D2, D3, and D4 that are input thereto. In some example embodiments, when a result obtained by duo-binary encoding the data D1 is the high level LEV_H, the signals H1, M1, and L1 may have a value of “100”.

The multiplexer 222 may sequentially select and output the duo-binary encoded signals H1, M1, L1, H2, M2, L2, H3, M3, L3, H4, M4, and L4 in units of data D1, D2, D3, and D4 based on the phase-shifted clock signals CK_p.

In some example embodiments, the multiplexer 222 may transmit the signals H1, M1, and L1 obtained by duo-binary encoding the first data D1 to the driver 223, and then, may sequentially transmit the signals H2, M2, L2, H3, M3, L3, H4, M4, and L4 obtained by duo-binary encoding the second data D2, the third data D3, and the fourth data D4 to the driver 223.

The phase-shifted clock signal generating circuit 226 may generate the phase-shifted clock signals CK_p based on an externally received clock signal CK. The phase-shifted clock signals CK_p may include the first phase-shifted clock signal CK_p1, the second phase-shifted clock signal CK_p2, the third phase-shifted clock signal CK_p3, and the fourth phase-shifted clock signal CK_p4 described with reference to FIG. 7. The phase-shifted clock signal generating circuit 226 does not generate the phase-shifted training clock signal CK_t.

The driver 223 may output an output voltage VOUT to a first node N1 based on duo-binary encoded signals H, M, and L input thereto. The first node N1 may be electrically connected to an output terminal TX_OUT of a transmitter.

The PHY interface 220 according to some example embodiments may include the equalizer 224 and the calibration circuit 225.

The equalizer 224 may perform an operation to secure a margin of the transmission signal transmitted to a communication channel CH. In some example embodiments, the equalizer 224 may compensate for an attenuation of the transmission signal when a level of the transmission signal is changed.

The calibration circuit 225 may control the driver 223 to ensure that the middle level LEV_M of the transmission signal is halfway (e.g., exactly halfway) between the high level LEV_H and the low level LEV_L.

Accordingly, the PHY interface 220 of the transmitter may reliably transmit the transmission signal using the equalizer 224 and the calibration circuit 225.

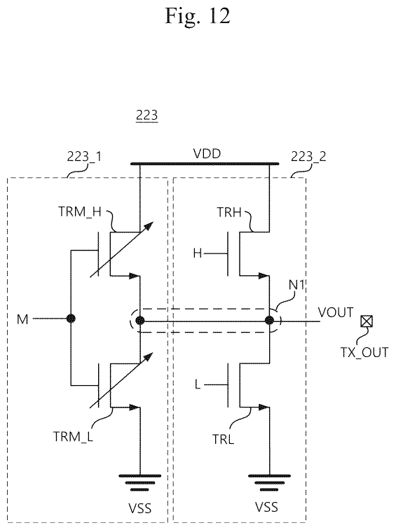

FIG. 12 is a circuit diagram illustrating the driver 223 of FIG. 11.

Referring to FIG. 12, the driver 223 may transmit the output voltage VOUT to the communication channel CH through the first node N1. The output voltage VOUT may have a voltage with one of the high level LEV_H, the middle level LEV_M, or the low level LEV_L.

The driver 223 may include a first stage circuit 223_1 and a second stage circuit 223_2, which are connected to the first node N1.

The first stage circuit 223_1 may include a first transistor TRM_H and a second transistor TRM_L, which are connected to each other in series through the first node N1 and receive a middle level signal M among the duo-binary encoding signals H, M, and L through a common gate node. The first transistor TRM_H and the second transistor TRM_L may be the same or similar type of transistor. In some example embodiments, each of the first transistor TRM_H and the second transistor TRM_L may be an n-type transistor.

The second stage circuit 223_2 may include a third transistor TRH and a fourth transistor TRL, which are connected to each other in series through the first node N1 and respectively receive a high level signal H and a low level signal L among the duo-binary encoding signals H, M, and L through a gate node thereof.

According to some example embodiments, each of the first transistor TRM_H and the second transistor TRM_L, which receives the middle level signal M, may be provided in plural. In some example embodiments, the output voltage VOUT output to the first node N1 by the first transistor TRM_H and the second transistor TRM_L based on the middle level signal M may be changed depending on the number of each of the first transistors TRM_H and the second transistors TRM_L, which is turned on in response to the middle level signal M.

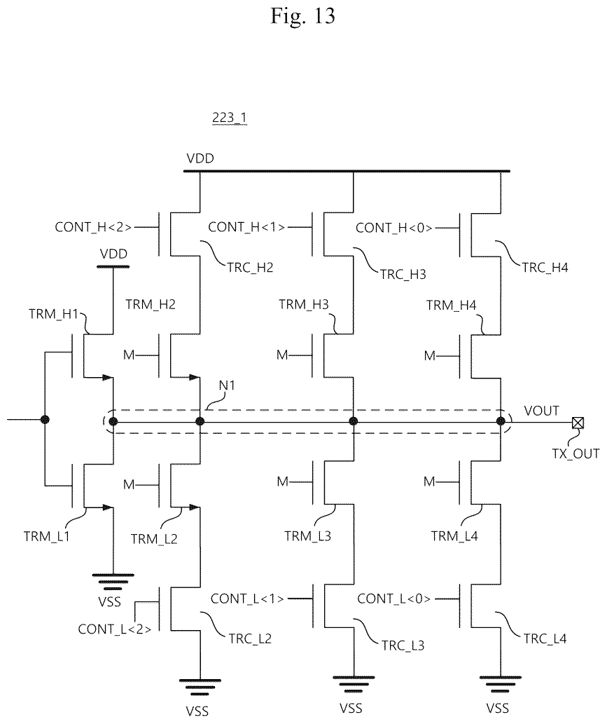

FIG. 13 is a circuit diagram illustrating the first stage circuit 223_1 of the driver 223 of FIG. 12. The first stage circuit 223_1 of the driver 223 will be described in detail with reference to FIGS. 12 and 13.

As described with reference to FIG. 12, each of the first transistor TRM_H and the second transistor TRM_L, which receives the middle level signal M, may be provided in plural.

FIG. 13 illustrates that the first transistor TRM_H includes four pull-up transistors TRM_H1, TRM_H2, TRM_H3, and TRM_H4. In addition, FIG. 13 illustrates that the second transistor TRM_L includes four pull-down transistors TRM_L1, TRM_L2, TRM_L3, and TRM_L4. According to some example embodiments, the first transistor TRM_H and the second transistor TRM_L may include fewer than four or more than four transistors.

The four pull-up transistors TRM_H1, TRM_H2, TRM_H3, and TRM_H4 that form the first transistor TRM_H may include a first main transistor TRM_H1 and second, third, and fourth auxiliary transistors TRM_H2, TRM_H3, and TRM_H4. In each of the second, third, and fourth auxiliary transistors TRM_H2, TRM_H3, and TRM_H4, a gate node may receive the middle level signal M, one of source and drain nodes may be connected to the first node N1, and the other of the source and drain nodes may be connected to a power electrode (or a power supply) VDD through first control transistors TRC_H2, TRC_H3, and TRC_H4.

Similarly, the four pull-down transistors TRM_L1, TRM_L2, TRM_L3, and TRM_L4 that form the second transistor TRM_L may include a second main transistor TRM_L1 and fifth, sixth, and seventh auxiliary transistors TRM_L2, TRM_L3, and TRM_L4. In each of the fifth, sixth, and seventh auxiliary transistors TRM_L2, TRM_L3, and TRM_L4, a gate node may receive the middle level signal M, one of source and drain nodes may be connected to the first node N1, and the other of the source and drain nodes may be connected to a ground electrode (or a ground supply) VSS through second control transistors TRC_L2, TRC_L3, and TRC_L4.

The first control transistors TRC_H2, TRC_H3, and TRC_H4 may receive a first control signal CONT_H through their gate nodes, and the second control transistors TRC_L2, TRC_L3, TRC_L4 may receive a second control signal CONT_L through their gate nodes.

A calibration controller 225_1 of FIG. 11 may output the first control signal CONT_H and the second control signal CONT_L of FIG. 13.

Referring to FIG. 11, the PHY interface 220 may input the data D1, D2, D3, and D4 encoded into the duo-binary signal with the middle level LEV_M to the duo-binary encoder 221 for a certain (or desired) period of time. The driver 223 may output the output voltage VOUT with the middle level LEV_M to the first node N1. A comparator 225_2 may compare the output voltage VOUT at the first node N1 with a reference voltage VREFM.

The calibration controller 225_1 may output the first control signal CONT_H and the second control signal CONT_L (collectively illustrated as control signal CONT) based on the comparison signal CP obtained by comparing the output voltage VOUT at the first node N1 with the reference voltage VREFM.

In some example embodiments, when the output voltage VOUT at the first node N1 is greater than the reference voltage VREFM, the calibration controller 225_1 may output the second control signal CONT_L to turn on at least one of the second control transistors TRC_L2, TRC_L3, and TRC_L4. Similarly, when the output voltage VOUT at the first node N1 is smaller than the reference voltage VREFM, the calibration controller 225_1 may output the first control signal CONT_H to turn on at least one of the first control transistors TRC_H2, TRC_H3, and TRC_H4.

Accordingly, the PHY interface 220 may transmit the transmission signal with the precise middle level LEV_M to the communication channel.

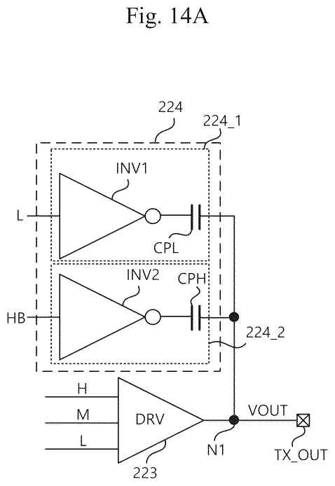

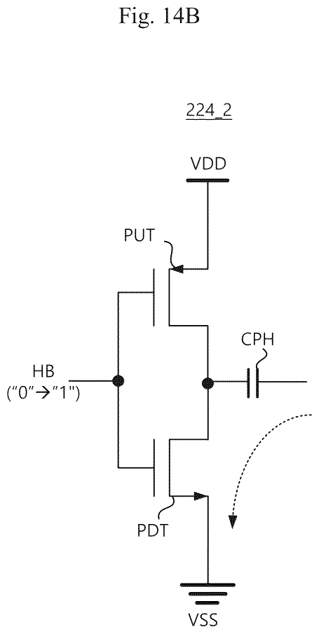

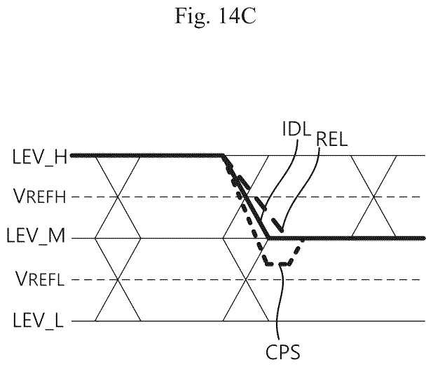

FIG. 14A is a circuit diagram illustrating the equalizer 224 of FIG. 11. FIG. 14B is a circuit diagram illustrating a second equalizer 224_2 of the equalizer 224. FIG. 14C is a diagram illustrating a variation in output voltage of the driver 223, which is caused by an operation of the equalizer 224.

Hereinafter, the equalizer 224 will be described with reference to FIGS. 11, 12, 14A, 14B, and 14C.

Referring to FIG. 14A, the equalizer 224 may include a first equalizer 224_1 and the second equalizer 224_2.

The first equalizer 224_1 may receive the low level signal L among the duo-binary encoding signals H, M, and L, and the second equalizer 224_2 may receive an inversion signal HB of the high level signal H.

The first equalizer 224_1 may include an inverter INV1 and a capacitor CPL, and the second equalizer 224_2 may include an inverter INV2 and a capacitor CPH. The first inverter INV1 and the second inverter INV2 may be a CMOS (complementary metal oxide semiconductor) based inverter circuit. Each of the first inverter INV1 and the second inverter INV2 may include a p-MOS pull-up transistor and an n-MOS pull-down transistor.

The inverters INV1 and INV2 may be connected to the first node N1 through the respective capacitors CPL and CPH.

FIG. 14B illustrates the operation of the second equalizer 224_2 when the output voltage VOUT is changed from the high level LEV_H to the middle level LEV_M as shown in FIG. 14C.

Referring to FIG. 14C, the output voltage VOUT from the driver 223 is expected to transition from the high level LEV_H to the middle level LEV_M in an ideal shape IDL, however, when the equalizer 224 is not employed, the output voltage VOUT may instead transition in a comparative shape REL due to attenuation.

When the output voltage VOUT from the driver 223 transitions from the high level LEV_H to the middle level LEV_M, the inversion signal HB with high level signal H among the duo-binary encoding signals H, M, and L input to a gate node of the second equalizer 224_2 may be changed from the value of “0” to the value of “1”. The pull-up transistor PUT of the second equalizer 224_2 may be turned off, and the pull-down transistor PDT of the second equalizer 224_2 may be turned on. Accordingly, the output voltage VOUT from the driver 223 may be pulled down (e.g., temporarily) to a voltage of the ground electrode through the capacitor CPH. As a result, although the output voltage VOUT is expected to transition in a compensated shape CPS of FIG. 14C, the output voltage VOUT may transition in the ideal shape IDL due to the attenuation.

The first equalizer 224_1 may operate in response to the second transition signal M2L and the third transition signal L2M.

In some example embodiments, the first equalizer 224_1 may pull down the output voltage VOUT in response to the second transition signal M2L where the output voltage VOUT is changed from the middle level LEV_M to the low level LEV_L. The first equalizer 224_1 may pull up the output voltage VOUT in response to the third transition signal L2M where the output voltage VOUT is changed from the low level LEV_L to the middle level LEV_M.

The second equalizer 224_2 may operate in response to the first transition signal H2M and the fourth transition signal M2H.

In some example embodiments, the second equalizer 224_2 may pull down the output voltage VOUT in response to the first transition signal H2M where the output voltage VOUT is changed from the high level LEV_H to the middle level LEV_M. The second equalizer 224_2 may pull up the output voltage VOUT in response to the fourth transition signal M2H where the output voltage VOUT is changed from the middle level LEV_M to the high level LEV_H.

Accordingly, the PHY interface 220 of the transmitter may secure the margin of the transmission signal and may transmit the transmission signal due to the equalizer 224 with improved reliability.

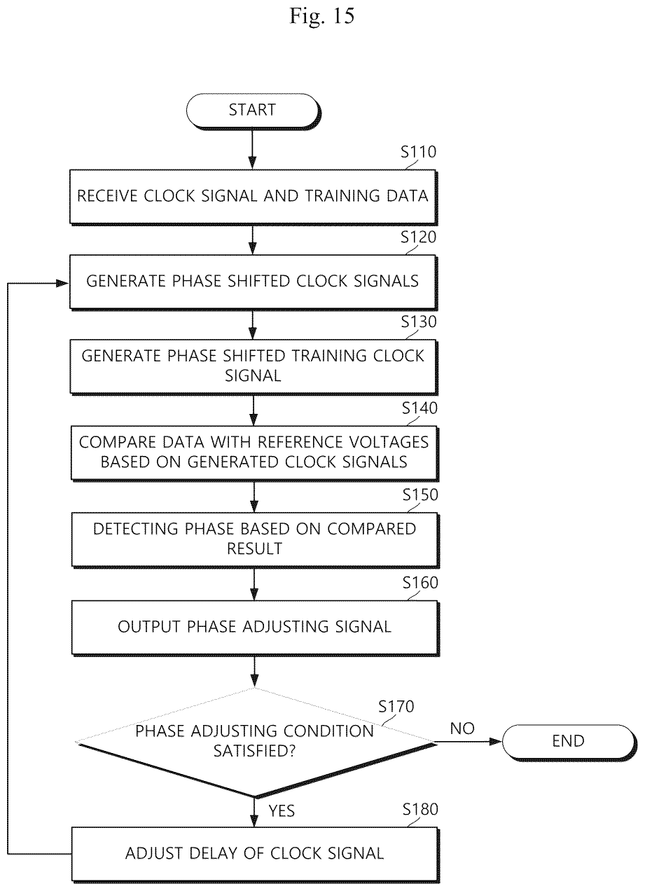

FIG. 15 illustrating a flowchart of a method of training the clock signal of the memory device, according to some example embodiments. The training operation of FIG. 15 may be performed in the memory device 100 of FIG. 1, for instance, under the control of the memory controller 210 of the host device 200. It is understood that additional operations can be provided before, during, and after the operations in FIG. 15, and some of the operations described below can be replaced or eliminated, for additional embodiments of the method. the order of the operations/processes may be interchangeable, or two or more operations can be performed simultaneously. The training method of the memory device 100 will be described with reference to FIGS. 1 and 15. Descriptions that are the same as or similar in some respects to those of the embodiments described with reference to FIGS. 1 to 14C will be not described again in detail.

Referring to FIG. 15, the PHY interface 120 of the memory device 100 may receive the clock signal and the training data (operation S110). The training data may be the duo-binary signal.

The PHY interface 120 may generate the phase-shifted clock signals based on the clock signal (operation S120). In some example embodiments, the phase-shifted clock signals may be the phase-shifted clock signals CK_p1, CK_p2, CK_p3, and CK_p4 described with reference to FIG. 7.

The PHY interface 120 may generate the phase-shifted training clock signal based on the clock signal (operation S130). In some example embodiments, the phase-shifted training clock signal may be the phase-shifted training clock signal CK_t described with reference to FIG. 7.

The PHY interface 120 may compare the training data with the reference voltages based on the phase-shifted clock signals (e.g., phase-shifted clock signals CK_p1, CK_p2, CK_p3, and CK_p4) and the phase-shifted training clock signal (e.g., phase-shifted training clock signal CK_t) (operation S140).

The PHY interface 120 may determine whether the phase of the phase-shifted clock signals is lagging or leading based on the compared result (operation S150).

The PHY interface 120 may output a phase adjusting signal (e.g., the delay control signal PH_EL) based on the phase of the phase-shifted clock signals (operation S160).

The PHY interface 120 may determine whether the phase adjusting signal satisfies a predetermined condition (operation S170).

When the phase adjusting signal is a signal that stops the training of the phase-shifted clock signals, the training of the clock signal may be stopped (operation S170).

When the phase adjusting signal is a signal that instructs the adjusting of the clock signals, the clock signal may be delayed relative to its previous state (operation S180). The PHY interface 120 may generate the phase-shifted clock signals based on the delayed clock signal in the operation S120.

Any or all of the elements described with reference to FIGS. 1, 2, 4, 5, 6, 10, 11, and/or 14A may communicate with any or all other elements described with reference to FIGS. 1, 2, 4, 5, 6, 10, 11, and/or 14A. For example, any element may engage in one-way and/or two-way and/or broadcast communication with any or all other elements in any of the figures, to transfer and/or exchange and/or receive information such as but not limited to data and/or commands, such as in a serial and/or parallel manner, via a bus such as a wireless and/or a wired bus. The information may be in encoded various formats, such as in an analog format and/or in a digital format, without being limited thereto.

As described herein, any devices, systems, modules, portions, units, controllers, circuits, and/or portions thereof according to any of the example embodiments, and/or any portions thereof (including, without limitation, the memory device 100, the memory cell array 110, the PHY interface 120, the phase adjusting circuit 121, the comparing circuit 125, the decoder 127, the memory controller 210, the PHY interface 220, the memory device 100A, the processor 200A, the plurality of core dies 130, the base die 140, the comparator 125_1, the first comparator 125_1A, the second comparator 125_1B, the non-return-to-zero (NRZ) converter and re-timer 125_2, the delay circuit 122, the clock signal generating circuit 123, the phase detecting circuit 124, the phase-shifted clock signal generating circuit 123_1, the phase-shifted training clock signal generating circuit 123_2, the level checking circuit 124_1, the transition checking circuit 124_2, the OR operation circuit 124_3, the first transition checking circuit 124_2A, the second transition checking circuit 124_2B, the third transition checking circuit 124_2C, the fourth transition checking circuit 124_2D, the duo-binary encoder 221, the multiplexer 222, the driver 223, the equalizer 224, the calibration circuit 225, the phase-shifted clock signal generating circuit 226, the calibration controller 225_1, the comparator 225_2, the driver 223, the first stage circuit 223_1, the second stage circuit 223_2, the first equalizer 224_1, the second equalizer 224_2, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device comprising:
a physical layer (PHY) interface; and
a memory cell array, the PHY interface comprising:
a phase adjusting circuit configured to generate a plurality of phase-shifted clock signals and a phase-shifted training clock signal based on a clock signal and configured to delay the clock signal based on a plurality of comparison signals output from a comparator;
the comparator configured to compare training data with each of a first reference voltage and a second reference voltage based on the plurality of phase-shifted clock signals and the phase-shifted training clock signal to output the plurality of comparison signals, the plurality of comparison signals including first comparison signals based on the plurality of phase-shifted clock signals, and second comparison signals based on the plurality of phase-shifted clock signals and the phase-shifted training clock signal; and
a decoder configured to perform a duo-binary decoding on the first comparison signals.

2. The memory device of claim 1, further comprising:
a buffer die comprising the PHY interface;
one or more core dies comprising the memory cell array and on the buffer die; and
one or more through-silicon vias penetrating through the one or more core dies.

3. The memory device of claim 1, wherein the second comparison signals are not input to the decoder.

4. The memory device of claim 1, wherein the plurality of phase-shifted clock signals have phases that are equally spaced from one another, and a phase of the phase-shifted training clock signal is located between adjacent phases of the phases of the plurality of phase-shifted clock signals.

5. The memory device of claim 1, wherein the phase adjusting circuit comprises:
a delay circuit configured to delay the clock signal;
a clock signal generating circuit configured to receive the delayed clock signal to generate the plurality of phase-shifted clock signals and the phase-shifted training clock signal; and
a phase detecting circuit configured to receive the second comparison signals to control a degree of delay of the delay circuit.

6. The memory device of claim 5, wherein the phase detecting circuit is configured to receive the second comparison signals,
the second comparison signals include one or more signals obtained from the phase-shifted training clock signal, a first phase-shifted clock signal, and a second phase-shifted clock signal,
the first phase-shifted clock signal and the second phase-shifted clock signal have phases adjacent to a phase of the phase-shifted training clock signal, and
the plurality of phase-shifted clock signals comprise the first phase-shifted clock signal and the second phase-shifted clock signal.

7. The memory device of claim 6, wherein the phase detecting circuit is configured to determine whether the delayed clock signal lags or leads the one or more signals obtained from the phase-shifted training clock signal.

8. The memory device of claim 6, wherein the phase detecting circuit is configured to determine a transition stage of the training data based on the first phase-shifted clock signal and the second phase-shifted clock signal of the second comparison signals.

9. The memory device of claim 1, wherein the training data includes a low level, a middle level, and a high level,
the training data comprises a plurality of transition stages, and
the plurality of transition stages comprise a first transition stage from the middle level to the high level, a second transition stage from the high level to the middle level, a third transition stage from the middle level to the low level, and a fourth transition stage from the low level to the middle level.

10. The memory device of claim 1, wherein the PHY interface further comprises:
an encoder configured to perform a duo-binary encoding on input data and to output a duo-binary signal; and
a driver configured to convert the duo-binary signal to a voltage signal and to transmit the voltage signal.

11. The memory device of claim 10, wherein the duo-binary signal comprises a high level signal, a middle level signal, and a low level signal, the driver is configured to transmit the voltage signal through a first node, and the driver comprises:
a first transistor configured to receive the middle level signal through a common gate node;
a second transistor connected to the first transistor in series through the first node and configured to receive the middle level signal through the common gate node;
a third transistor configured to receive the high level signal through a gate node thereof; and
a fourth transistor connected in series with the third transistor through the first node and configured to receive the low level signal through a gate node thereof.

12. The memory device of claim 11, further comprising:
a first CMOS inverter circuit configured to receive a high-level inversion signal obtained by inverting the high level signal through the common gate node;
a second CMOS inverter circuit configured to receive the low level signal through the common gate node;
a first capacitor connected to the first CMOS inverter circuit and the first node; and
a second capacitor connected to the second CMOS inverter circuit and the first node.

13. The memory device of claim 12, wherein the first CMOS inverter circuit is configured to pull down the voltage signal when a level of the voltage signal is changed from a high level to a middle level and is configured to pull up the voltage signal when the voltage signal is changed from the middle level to the high level.

14. The memory device of claim 12, wherein the second CMOS inverter circuit is configured to pull up the voltage signal when a level of the voltage signal is changed from a low level to a middle level and is configured to pull down the voltage signal when the level of the voltage signal is changed from the middle level to a low level.

15. The memory device of claim 11, further comprising:
a plurality of pull-up transistors connected to the first node in parallel to the first transistor and configured to receive the middle level signal through a gate node thereof;
a plurality of pull-down transistors connected to the first node in parallel to the second transistor and configured to receive the middle level signal through a gate node thereof;
first control transistors, each configured to connect a corresponding pull-up transistor among the pull-up transistors to a power electrode; and
second control transistors, each configured to connect a corresponding pull-down transistor among the pull-down transistors and a ground electrode.

16. The memory device of claim 15, further comprising a calibration circuit that is configured to compare the middle level signal output from the driver with a reference voltage of the middle level signal, control the first control transistors and the second control transistors, and calibrate the middle level signal output from the driver.

17. A memory device comprising:
a buffer die comprising a PHY interface;
a core die comprising a memory cell array and on the buffer die; and
a through-silicon via penetrating through the core die,
the PHY interface comprising:
a clock signal generating circuit configured to generate a plurality of phase-shifted clock signals based on a clock signal;
a comparator configured to compare a received data signal sampled based on the phase-shifted clock signals with each of a first reference voltage and a second reference voltage and configured to output first comparison signals;
a decoder configured to perform a duo-binary decoding on the first comparison signals;
a delay circuit configured to delay the clock signal; and
a phase detecting circuit configured to control the delay circuit,
wherein the phase detecting circuit is further configured to generate a phase-shifted training clock signal having a phase different from the phase-shifted clock signals during a training operation,
wherein the comparator is further configured to output second comparison signals obtained by comparing the received data signal sampled based on the phase-shifted training clock signal with each of the first reference voltage and the second reference voltage during the training operation, and
wherein the phase detecting circuit is configured to control the delay circuit based on the first comparison signals and the second comparison signals during the training operation.

18. The memory device of claim 17, wherein the second comparison signals based on the phase-shifted training clock signal are not input to the decoder.

19. The memory device of claim 17, wherein the phase-shifted clock signals have phases that are equally spaced from one another, and a phase of the phase-shifted training clock signal is located between adjacent phases of the phases of the phase-shifted clock signals.

20. A system-in-package comprising:
a package substrate;
an interposer on the package substrate; and
a memory device and a system-on-chip on the interposer, the memory device comprising:
a buffer die comprising a PHY interface;
core dies on the buffer die; and
a through-silicon via penetrating through the core dies, the PHY interface comprising:
a phase adjusting circuit configured to generate a plurality of phase-shifted clock signals and a phase-shifted training clock signal based on a clock signal received from the system-on-chip and configured to delay the clock signal based on a plurality of comparison signals output from a comparator;
the comparator configured to compare training data received from a memory controller with each of a first reference voltage and a second reference voltage based on the phase-shifted clock signals and the phase-shifted training clock signal to output the plurality of comparison signals; and
a decoder configured to perform a duo-binary decoding on the comparison signals based on the phase-shifted clock signals.
